(19) United States
(12) Patent Application Publication
(10) Pub. No.: US 2013/0240261 A1
(43) Pub. Date: Sep. 19, 2013

(54) COMPOSITE MATERIAL FOR SHIELDING ELECTROMAGNETIC WAVE

(71) Applicants: Kyong Hwa Song, Seoul (KR); Han Saem Lee, Ansan (KR); Jin Woo Kwak, Suwon (KR); Byung Sam Choi, Suwon (KR)

(72) Inventors: Kyong Hwa Song, Seoul (KR); Han Saem Lee, Ansan (KR); Jin Woo Kwak, Suwon (KR); Byung Sam Choi, Suwon (KR)

(73) Assignee: HYUNDAI MOTOR COMPANY, Seoul (KR)

(21) Appl. No.: 13/480,839

(22) Filed: May 25, 2012

(30) Foreign Application Priority Data
Mar. 19, 2012 (KR) 10-2012-0027850

(51) Int. Cl. H05K 9/00; B82Y 99/00; B82Y 30/00

(52) U.S. Cl. 174/391; 977/734; 977/932

(57) ABSTRACT

The present disclosure provides a composite material for shielding an electromagnetic wave, and more particularly, a composite material for shielding an electromagnetic wave, which can effectively shield an electromagnetic wave generated in an electronic component. The composite material of the disclosure has a multi-layer structure including: an electromagnetic wave-shielding layer for shielding an electromagnetic wave; and a thermally conductive layer stacked under the electromagnetic wave-shielding layer for dissipating heat generated when the electromagnetic wave is absorbed, wherein the electromagnetic wave-shielding layer includes a material including a magnetic material and a carbon-based conductive material added to a thermoplastic resin.

### CROSS-REFERENCE TO RELATED PATENT APPLICATION

This application claims under 35 U.S.C. §119(a) the benefit of Korean Patent Application No. 10-2012-0027850, filed on Mar. 19, 2012, in the Korean Intellectual Property Office, the disclosure of which is incorporated herein in its entirety by reference.

### BACKGROUND OF THE INVENTION

1. Field of the Invention

The present invention relates to a composite material for shielding an electromagnetic wave. More particularly, the present invention relates to a composite material for shielding an electromagnetic wave, which can effectively shield an electromagnetic wave generated in an electronic component.

2. Description of the Related Art

Many electronic parts are increasingly required to be lightweight and have various shapes and designs because of the expansion of the use of electronic equipments in vehicles, as well as the rapid increase in the use of mobile displays. In order to meet these demands, there is a continuous desire to use plastic as the material for these types of parts. Plastic is lightweight and, through molding, its design can be easily changed to various shapes; therefore, its use in electronics applications will likely continue to increase. Disadvantageously, plastic cannot be used as a housing material for electronic parts that require electromagnetic wave shielding because it does not have the conductivity of metal. Further, because most plastics are intrinsically electric insulators, electromagnetic waves can easily pass through a plastic polymer without any loss, or dissipation, thereto. This characteristic may cause a big problem when the polymer is used for the case of electronic equipment such as computers, mobile phones, and the like.

In order to solve the drawbacks of plastic, research has focused on preparing a composite by adding a filler having excellent conductivity. For example, the electromagnetic wave shielding of a plastic composite may be produced by dispersing at least 30 vol % of a metal powder having excellent electrical conductivity throughout the plastic, or by using carbon fiber to an amount of 30 volume % or more in a polymer, such as silicone rubber, polyurethane, polycarbonate, epoxy resin, and the like. It is known that the use of a metal powder, such as, e.g., silver (Ag) powder or silver coated copper (Ag-coated Cu), has excellent electrical conductivity when dispersed in the polymer to the amount of 30 volume %, and it is possible to obtain a volume resistance of 0.01 Ω-cm or less and achieve a shielding efficiency of about 50 dB.

In order to comply with the electromagnetic wave shielding standards, which have recently become quite strict, it is now necessary to achieve a lower volume resistivity and a higher shielding effect. To this end, it is necessary to disperse a larger quantity of metal powder, such as silver powder, in the polymer. However, when such a large quantity of silver powder is dispersed in the polymer, the electromagnetic wave shielding effect may be improved by the improvement of the electrical conductivity, however, the mechanical properties of the material, such as impact strength, are degraded. Consequently, there are many significant limitations in the application of a metal powder as an electromagnetic wave shielding material. Therefore, there is an urgent need for the development of an electromagnetic wave shielding material that is inexpensive, light-weighted, strong, easy to prepare and process, and durable under various environmental conditions.

An electromagnetic wave has wavelengths in which an electrical wave and a magnetic wave coexist. Material having a high dielectric constant and high conductivity is required to shield an electrical field, and metal having high permeability is also useful to shield a magnetic field. Thus, it is not easy to use only one material for electromagnetic wave shielding, and material in which two or more materials are hybridized, is preferred for electromagnetic wave shielding. In addition, a method of structuring a material so that desired characteristics of these materials may be displayed is required.

Most of an electromagnetic wave in metal is shielded by reflection. That is, if an electromagnetic wave transferred via air contacts the surface of a metal, an eddy current occurs in the conductor due to electromagnetic induction, and the eddy current reflects the electromagnetic wave. Consequently, the reflected electromagnetic wave may affect another component and thus secondary electromagnetic wave damage may be generated.

The principle addressing the ability to shield electromagnetic wave in a plastic including a conductive filler, may be described by the following mechanism: the electromagnetic wave is transferred via air, contacts a surface of another medium, and part of the electromagnetic wave is reflected, while the other part is transmitted into the medium. Once transmitted into the medium, the waves will become weak and dissipate due to multi-reflection or absorption when the waves meet a conductive nano-material inside of the polymer medium, or the electromagnetic waves may be extinguished, and only parts of the waves are transmitted. In other words, many of the electromagnetic waves are extinguished by being reflected or absorbed by fillers in the polymer composite. These absorbed electromagnetic waves create electron flow by vibrating electrons, and at this time, current is generated. Commonly, electron movement is emitted as heat energy, which makes continuous absorption of the electromagnetic field possible. However, if it is not emitted through heat energy or removed otherwise removed, the shielding effect may decrease over time. Therefore, heat energy removal may be correlated to increasing shielding efficiency. Accordingly, in order to shield the electromagnetic waves, the composite should ultimately contain both a material with a good electrical conductivity and a material with a good heat transfer.

Generally, in the case of an electronic component, an electromagnetic wave or heat generated by an electronic component disposed on an electronic substrate is dispersed into the case. In this case, the electromagnetic wave that contacts the metal case is reflected back to the electronic component. Thus, in order to shield the electromagnetic wave, it is preferable to deposit an electromagnetic wave-absorbing material on the surface of a case that covers the electronic substrate, in order to prevent secondary reflection and to transfer heat generated by absorption of the electromagnetic wave to the outside. In addition, it is preferable that heat generated by the continuous operation of the electronic component is also absorbed on the surface of the case and thus is dissipated to the outside. In particular, a heat sink may be attached to a lower portion of an inverter, or the like, in which a large amount of heat is generated during driving, in order to induce heat-dissipation. At present, a method of improving thermal conductivity of a contact portion between the electronic substrate and the heat sink by has generally involved the use of grease or an adhesive. However, this technology does not consider electromagnetic wave-shielding, and thus an electromagnetic wave generated in a downward direction of an electronic component is re-reflected by the heat sink.

Attempts have been made to create a material having both a shielding performance and a heat-dissipation performance by manufacturing a composite material by adopting aluminum, iron, silver, magnetic, etc. as a shielding material and metal or ceramic powder as a thermally conductive material and by mixing the shielding material and the thermally conductive material in a single layer. Unfortunately, it has been very difficult to achieve uniform dispersion of the conductive and shielding fillers in such materials. Consequently, an electromagnetic wave may transmit through the plastic without passing through the shielding material, as a result of shielding gaps produced by the uneven dispersion.

Accordingly, there is a need in the art to develop composite materials that have excellent electrical conductivity and heat transfer/dissipation properties.

### SUMMARY OF THE INVENTION

The present invention provides a composite material for shielding an electromagnetic wave. In an exemplary embodiment, the material is configured as a multi-layer structure in which a layer formed of an electromagnetic wave-shielding material including an electromagnetic wave-absorbing material and a layer formed of a thermally conductive material including material having a high thermally conductive performance are stacked and combined with one another, has both an electromagnetic wave-shielding performance and a heat-dissipation performance, can absorb an electromagnetic wave generated in an electronic component and simultaneously dissipate heat generated by the absorbed electromagnetic wave to the outside.

According to an aspect of the present invention, there is provided a composite material for shielding an electromagnetic wave, the composite material having a multi-layer structure including: an electromagnetic wave-shielding layer for shielding an electromagnetic wave; and a thermally conductive layer stacked under the electromagnetic wave-shielding layer for dissipating heat generated when the electromagnetic wave is absorbed. Additionally, the electromagnetic wave-shielding layer may include a magnetic material and a carbon-based conductive material (e.g., carbon nanotube) added to a thermoplastic resin. In a preferred embodiment, the thermally conductive layer may include a material such as, for example, graphene nanoplate based on a thermoplastic resin.

In another preferred embodiment, the electromagnetic wave-shielding layer may include a material including 5 to 40 parts by weight of a magnetic material and 0.1 to 20.0 parts by weight of a carbon-based conductive material based on 100 parts by weight of the thermoplastic resin.

In still another preferred embodiment, the thermally conductive layer may include 0.1 to 20.0 parts by weight of the graphene nanoplate based on 100 parts by weight of a thermoplastic resin.

In still another preferred embodiment, the electromagnetic wave-shielding layer may have the shape of a film having a thickness of 10 to 300 μm, and the thermal conductive layer may have a thickness of 0.5 to 5 mm.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a composition of a composite material for shielding an electromagnetic wave according to an exemplary embodiment of the present invention; and

FIG. 2 is a graph showing comparison of a result of measuring an electromagnetic wave-shielding performance of the composite material for shielding an electromagnetic wave illustrated in FIG. 1 and an electromagnetic wave-shielding performance of material for shielding an electromagnetic wave according to the conventional art.

### DETAILED DESCRIPTION OF THE INVENTION

Hereinafter reference will now be made in detail to various embodiments of the present invention, examples of which are illustrated in the accompanying drawings and described below. While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Ranges provided herein are understood to be shorthand for all of the values within the range. For example, a range of 1 to 50 is understood to include any number, combination of numbers, or sub-range from the group consisting of 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50, as well as all intervening decimal values between the aforementioned integers such as, for example, 1.1, 1.2, 1.3, 1.4, 1.5, 1.6, 1.7, 1.8, and 1.9. With respect to sub-ranges, “nested sub-ranges” that extend from either end point of the range are specifically contemplated. For example, a nested sub-range of an exemplary range of 1 to 50 may comprise 1 to 10, 1 to 20, 1 to 30, and 1 to 40 in one direction, or 50 to 40, 50 to 30, 50 to 20, and 50 to 10 in the other direction.

The present invention provides a composite material having a multi-layer structure that includes a layer for shielding an electromagnetic wave and a layer for dissipating heat generated when the electromagnetic wave is absorbed by the layer, to the outside, in order to improve electromagnetic wave-shielding efficiency. Thus, a composite material for shielding an electromagnetic wave according to the present invention may be characterized by being configured to have a multi-layer structure including a layer formed of an electromagnetic wave-shielding material and a layer formed of a thermally conductive material for dissipating heat generated when the electromagnetic wave is absorbed by the layer to the outside.

In view of absorbing an electromagnetic wave, it may be important to form a network in the direction of the thickness of the material, but a better shielding effect is obtained when a compact network between materials is formed on their surfaces. For example, an electromagnetic wave having various wavelengths is filtered by conductive materials that are compactly connected (i.e. the wave does not pass through the conductive materials). However, if the conductive materials are loosely connected, the shorter wavelengths of the electromagnetic wave are not filtered by the conductive material and may pass therethrough.

A metal material that is generally used has a lattice structure and can shield an electromagnetic wave while forming a compact electronic cloud. However, a plastic material having a matrix structure does not block the electromagnetic wave, and the electromagnetic wave passes through the plastic material. As a filler for shielding added to the plastic material constitutes a more compact network, electromagnetic wave-shielding efficiency is improved. Thus, a composite material in the form of a thin film having a high density between shielding fillers may be manufactured compared to a composite material having a large distance between shielding fillers and having a predetermined thickness.

Thus, according to the present invention, a layer for shielding an electromagnetic wave is manufactured in the form of a film, and an added shielding material is compressed with high force. In addition, since a high surface distribution density of a magnetic material that is an electromagnetic wave-shielding material is required to absorb an electromagnetic wave emitted from an electronic component, the content ratio of the surface of the magnetic material with respect to the inside of the magnetic material is increased.

Thus, an electromagnetic wave-shielding layer of a composite material for shielding an electromagnetic wave according to an exemplary embodiment of the present invention may be manufactured in the form of a film by mixing a magnetic material having high electromagnetic wave-absorbing and high shielding capabilities with material to which carbon nanotube (CNT) (carbon-based conductive material) is added. Here, the magnetic material has a characteristic in that, if an electromagnetic wave is applied to the magnetic material, the magnetic material absorbs the energy while the amount of rotation and translation of molecules is increased due to the polarity of the magnetic material and the polarity of the electromagnetic wave. Thus, a thermally conductive layer of the composite material for shielding an electromagnetic wave according to an exemplary embodiment of the present invention may absorb heat generated by shielding the electromagnetic wave, and may be manufactured using material to which graphene nanoplate having high thermal conductivity is added. The graphene nanoplate may have a shape in which 4 to 7 layers of graphene are stacked in a plate structure with a nano-thickness. Thus, the graphene nanoplate may absorb all wavelengths of an electromagnetic wave and may also have high thermal conductivity with a thermally conductive value of 200 to 300 W/mK.

Hereinafter, the composite material for shielding a magnetic material according to the present invention will be described in more detail.

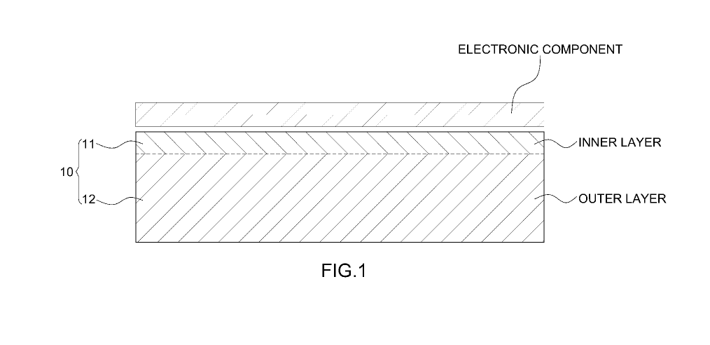

FIG. 1 is a cross-sectional view of a composition of the composite material 10 for shielding an electromagnetic wave according to an exemplary embodiment of the present invention. As illustrated in FIG. 1, the composite material 10 for shielding an electromagnetic wave according to the present exemplary embodiment includes an electromagnetic wave-shielding layer 11 that is a type of conductive film including a magnetic material having a high electromagnetic wave-absorbing performance, and a thermally conductive layer 12 including graphene nanoplate having high thermal conductivity. The composite material 10 for shielding an electromagnetic wave illustrated in FIG. 1 has a multi-layer structure in which the electromagnetic wave-shielding layer 11 and the thermally conductive layer 12 are separately formed and stacked.

The composite material 10 for shielding an electromagnetic wave according to an exemplary embodiment of the present invention may maintain a continuous shielding effect in which an electromagnetic wave generated in an electronic component is absorbed by the composite material 10 while passing through the electromagnetic wave-shielding layer 11. Heat generated by the absorbed electromagnetic wave is easily dissipated via the thermally conductive layer 12, so that heat generated in the electromagnetic wave-shielding layer 11 when the electromagnetic wave is absorbed by the composite material 10 is not accumulated, but rather is removed. Additionally, heat that may be generated during a long-term use of the electronic component is also removed, thereby preventing the performance of the electronic component from being lowered due to the electromagnetic wave and heat.

According to an exemplary embodiment of the invention, the electromagnetic wave-shielding layer 11 is formed as an upper layer of the composite material 10 for shielding an electromagnetic wave generated in the electronic component, and is formed of material in which a magnetic material and CNT (conductive nano-material) are added to, and dispersed into, a thermoplastic resin that is a matrix resin.

The magnetic material may be based on a metal having high permeability, such as iron (Fe), cobalt (Co), nickel (Ni), or the like, or a compound including metal. One metal-based material or metal-based compound may be solely used as the magnetic material, or two or more metal-based materials and/or metal-based compounds may be mixed and used as the magnetic material. Since Fe generally has the highest permeability among these metals, it may be used as a main component of the magnetic material in a preferred embodiment. For example, the electromagnetic wave-shielding layer 11 may be formed in the form of a film by using thermoplastic resin to which Fe(CO) as a metal-based compound is added. In this exemplary embodiment, 5 to 40 parts by weight of the magnetic material based on 100 parts by weight of the thermoplastic resin may be used. When 5 or less parts by weight of the magnetic material based on 100 parts by weight of the thermoplastic resin is used, the magnetic material is not sufficiently dispersed into the matrix resin, and when 40 or more parts by weight of the magnetic material is used, a material property of the electromagnetic wave-shielding layer is lowered, which is not preferable.

In addition, 0.1 to 20.0 parts by weight of the CNT based on 100 parts by weight of the thermoplastic resin may be used. When 0.1 or less parts by weight of the CNT based on 100 parts by weight of the thermoplastic resin is used, improvements in shielding characteristics of the electromagnetic wave-shielding layer may not be expected due to the addition of the CNT. When 20 or more parts by weight of the CNT based on 100 parts by weight of the thermoplastic resin is used, the amount of the added CNT is excessive, and thus, it is not easy to form the electromagnetic wave-shielding layer 11 in the form of a film.

As mentioned above, the electromagnetic wave-shielding layer 11 is formed in the form of a film in such a way that the magnetic material is compressed with high force and has a high surface distribution density. In detail, the electromagnetic wave-shielding layer 11 is formed in the form of a film having a thickness of 10 to 300 μm. When the electromagnetic wave-shielding layer 11 has a thickness of less than 10 μm, deformation occurs when the electromagnetic wave-shielding layer 11 is compressed with a thermally conductive layer, and it is not easy to maintain a uniform form as the electromagnetic wave-shielding layer 11. When the electromagnetic wave-shielding layer 11 has a thickness of greater than 300 μm, stability and shielding efficiency in its thickness direction are not ideal when the electromagnetic wave-shielding layer 11 is attached to the thermally conductive layer.

The matrix resin of the electromagnetic wave-shielding layer 11 may be the thermoplastic resin, in particular, a mixture including one or more selected from the group consisting of polyethylene, polypropylene, polystyrene, polyalkylene terephthalate, polyamide resin, polyacetal resin, polycarbonate, polysulfone, and polyimide.

Preferably, the thermoplastic resin may be a crystalline thermoplastic resin. A crystalline thermoplastic resin is preferred because it has characteristics that it takes a crystalline region of plastic when crystallized, and makes a filler for shielding, i.e., a magnetic material and/or CNT may be pushed to the outside (e.g., the outer surface) of the crystalline thermoplastic resin. Thus, a more efficient conductive path is formed in the crystalline thermoplastic resin than in non-crystalline resin.

The electromagnetic wave-shielding layer 11 is formed using a T-Die construction method and may be manufactured in the form of a casting polypropylene film. Preferably, the electromagnetic wave-shielding layer 11 may be manufactured by patterning its surface in a shaded stripe, lattice, or the like. The patterning process enables the electromagnetic wave-shielding layer 11 to be more stably attached to the thermally conductive layer when being compressed with the thermally conductive layer having thermal conductivity.

The thermally conductive layer 12 may be formed as a lower layer of the composite material 10 for shielding the electromagnetic wave generated in the electronic component. The thermally conductive layer 12 may be formed of a material in which graphene nanoplate having high thermal conductivity is added to thermoplastic resin that is a matrix resin and is dispersed into the thermoplastic resin, in order to dissipate heat generated when an electromagnetic wave is absorbed by the electromagnetic wave-shielding layer 11 to the outside, or exterior surface.

The thermoplastic resin of the thermally conductive layer 12 may be the same resin as that of the above-mentioned electromagnetic wave-shielding layer 11.

The graphene nanoplate is a material having a plate shape in which 4 to 7 layers of graphene are stacked, which has high thermal conductivity and absorbs all wavelengths of an electromagnetic wave. Graphene nanoplate having a thickness of 10 to 100 nm and a length of 5 to 50 μm may be used according to an exemplary embodiment of the invention. When the thickness of the graphene nanoplate is less than 10 nm, the process cost for separating the graphene nanoplate from graphene nanoplate powder increases. When the thickness of the graphene nanoplate exceeds 100 nm, the weight ratio of the composite material increases without any additional increase in thermal conductivity, which is not preferable. According to a preferred embodiment, 0.1 to 20.0 parts by weight of the graphene nanoplate based on 100 parts by weight of the thermoplastic resin that is the matrix resin may be used. When 0.1 or less parts by weight of the graphene nanoplate based on 100 parts by weight of the thermoplastic resin are used, it is not easy to form a sufficient network between graphene nanoplates dispersed into the thermoplastic resin. When 20 or more parts by weight of the graphene nanoplate based on 100 parts by weight of the thermoplastic resin are used, injection molding of the thermally conductive layer is not easily performed, which is not preferable.

The graphene nanoplate and the thermoplastic resin are melted and mixed at a temperature of 180 to 300° C. If a temperature for melting and mixture is less than 180° C., the matrix resin is not sufficiently melted, and a filler (graphene nanoplate) may not be uniformly mixed in the matrix resin. If the temperature for melting and mixture exceeds 300° C., plastic chain scission of the matrix resin is accelerated, and the mechanical material properties of the thermally conductive layer are lowered, which is not preferable.

Thus, the thermally conductive layer 12 is formed to have a thickness of 0.5 to 5.0 mm. When the thermally conductive layer 12 has a thickness of less than 0.5 mm, it is not easy to maintain durability of the material for use as a case for an electronic component. When the thermally conductive layer 12 has a thickness of greater than 5.0 mm, the whole thickness (the whole thickness of the composite material 10 for shielding an electromagnetic wave) formed when the thermally conductive layer 12 is combined with the electromagnetic wave-shielding layer 11, increases greatly, thereby increasing the weight of the material, which is not desirable.

Furthermore, the composite material 10 for shielding an electromagnetic wave illustrated in FIG. 1 may contain various additives, such as an antioxidant, a coloring agent, a backing agent, a lubricant, and an optical stabilizer. The amount of these additives may be properly adjusted in consideration of various factors known to one of skill in the art, including the desired use and functional characteristics.

The composite material 10 for shielding an electromagnetic wave having the above structure illustrated in FIG. 1 according to the present invention is a plastic composite material having a multi-layer structure for effectively shielding an electromagnetic wave generated in an electronic component. The composite material 10 for shielding an electromagnetic wave is configured by stacking the electromagnetic wave-shielding layer 11 having an excellent electromagnetic wave-absorbing performance and the thermally conductive layer 12 for dissipating heat generated when the electromagnetic wave is absorbed by the electromagnetic wave-shielding layer 11 to the outside. The composite material 10 for shielding an electromagnetic wave may be used to improve an electromagnetic wave-shielding performance of a case for an electronic component, for example. In this case, the electromagnetic wave-shielding layer 11 forms an inner layer of the case that covers the electronic component, and the thermally conductive layer 12 forms an outer layer of the case.

In the composite material 10 for shielding an electromagnetic wave illustrated in FIG. 1 according to an exemplary embodiment of the present invention, the electromagnetic wave dissipated from the electronic component is firstly absorbed by the electromagnetic wave-shielding layer 11, and heat generated when the electromagnetic wave is absorbed by the electromagnetic wave-shielding layer 11, is secondarily dissipated by the thermally conductive layer 12, thereby improving overall electromagnetic wave-shielding efficiency. In addition, since the composite material 10 for shielding an electromagnetic wave has both an electromagnetic wave-shielding performance and thermal conductivity, when the composite material 10 is applied to the electronic component, it shows electromagnetic wave-shielding and heat-dissipation effects simultaneously. Thus, the composite material 10 may be applied to various types of cases for electronic components such as, for example, those of a car, mobile phones, displays, and the like.

The present invention will now be described more fully with reference to the accompanying drawings, in which exemplary embodiments of the invention are shown. However, the present invention is not limited by the following embodiments.

### Example

### Manufacturing Composite Material for Shielding Electromagnetic Wave Having Two-Layer Structure

Fe(CO) powder and CNT powder were dried, mixed at a weight ratio of 5:1, added to polypropylene, and melted using a T-Die construction method without drawing, thereby forming a conductive film having a thickness of 100 μm, i.e., an electromagnetic wave-shielding film.

In this exemplary embodiment, the conductive film was manufactured to entirely include a filler of 18 weight percent, and the manufactured film was cut in a size of 120×120 mm, and thus an electromagnetic wave-shielding film was manufactured.

### Manufacturing Thermally Conductive Film for Dissipating Heat

After 10 parts by weight of graphene nanoplate having an average thickness of 40 nm and an average length of 20 μm based on 100 parts by weight of polypropylene was used, they were uniformly mixed at a melting temperature of 230° C. at 100 rpm by using a Haake extruder and a mixer to produce a pellet type of compound, which was then manufactured by performing injection molding to produce a thermally conductive film having a thickness of 1.5 mm and a size of 100×100 mm.

### Manufacturing Composite Material for Shielding Electromagnetic Wave

A composite material for shielding an electromagnetic wave having a two-layer structure was manufactured by stacking and compressing and forming a thermally conductive film under the previously-manufactured electromagnetic wave-shielding material.

### Comparative Example

### Manufacturing Composite Material for Shielding Electromagnetic Wave Having a Single Layer Structure

Simultaneously with adding the same amount of the mixed powder of Fe(CO) and CNT included in the electromagnetic wave-shielding film obtained in the embodiment to polypropylene, 10 parts by weight of graphene nanoplate having an average thickness of 40 nm and an average length of 20 μm based on 100 parts by weight of polypropylene was used, and they were uniformly mixed at a melting temperature of 230° C. at 100 rpm by using a Haake extruder and a mixer to prepare a pellet type of compound material, which was then manufactured by performing injection molding to produce a thermally conductive film having a thickness of 1.6 mm.

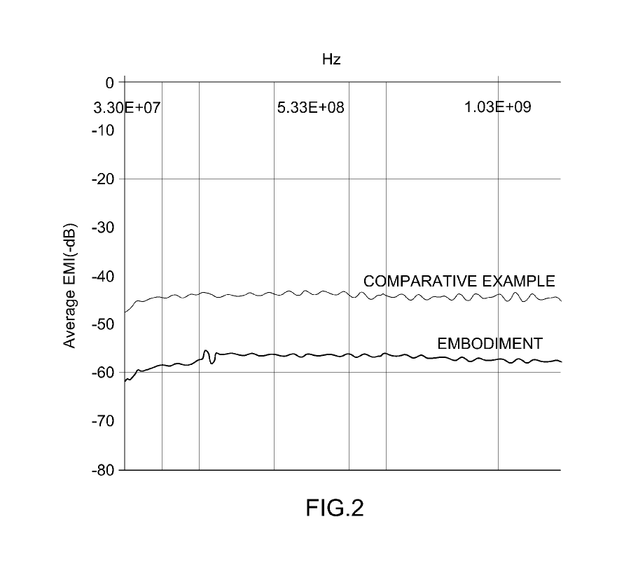

As a result of measuring electromagnetic wave-shielding performances of the composite materials manufactured according to the embodiment and the comparative example, respectively, by using an electromagnetic wave-shielding measuring device E 8362B Aglient, as illustrated in FIG. 2, the composite material manufactured according to the exemplary embodiment has a higher electromagnetic wave-shielding performance than the composite material manufactured according to the comparative example.

Thus, even though the same amount of shielding filler is used, when a composite material having a multi-layer structure is manufactured, a higher shielding performance can be obtained compared to the case of a composite material having a single layer structure.

In detail, simultaneously with an electromagnetic wave being sufficiently shielded by the electromagnetic wave-shielding film including the electromagnetic wave-absorbing material, heat is transferred to the thermally conductive film including a thermally conductive material, and heat generated when the electromagnetic wave is absorbed by the electromagnetic wave-shielding layer, is not accumulated, but rather is dissipated to the outside so that continuous electromagnetic wave-shielding is promoted and the composite material manufactured according to the embodiment shows a higher electromagnetic wave-shielding performance.

As described above, in a composite material for shielding an electromagnetic wave according to the present invention, after an electromagnetic wave-shielding layer and a thermally conductive layer having different transfer mechanisms are formed, they are stacked and combined with each other so that an electromagnetic wave-absorbing performance is increased to improve a shielding effect, and heat generated when the electromagnetic wave is absorbed by the electromagnetic wave-shielding layer, is effectively dissipated to the outside so that the maximum shielding and heat-dissipation effect can be obtained from each of the electromagnetic wave-shielding and thermally conductive layers.

Thus, the composite material for shielding an electromagnetic wave according to the present invention has a multi-layer structure including an upper layer formed of a magnetic material having excellent electromagnetic wave-absorbing and shielding performances and a conductive nano-material (carbon nanotube) and a lower layer including graphene nanoplate having high thermal conductivity so that an electromagnetic wave generated in an electronic component is absorbed/shielded and simultaneously, heat generated when the electromagnetic wave is absorbed by the multi-layer structure, is dissipated by the lower layer, and the generated heat is not accumulated, but rather is removed to maintain a continuous shielding effect and thus the upper layer enables a continuous electromagnetic wave-absorbing performance to improve an electromagnetic wave-shielding performance.

Thus, the composite material for shielding an electromagnetic wave according to the present invention may be applied to various fields that require electromagnetic wave-shielding and heat-dissipation performances, such as electronic components of a car, mobile phones, display devices, and the like.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A composite material for shielding an electromagnetic wave, comprising:
an electromagnetic wave-shielding layer comprising a magnetic material and a carbon-based conductive material added to a thermoplastic resin; and
a thermal conductive layer, wherein the thermal conductive layer is stacked under the electromagnetic wave-shielding layer.

2. The composite material of claim 1, wherein the thermal conductive layer comprises graphene nanoplate based on a thermoplastic resin.

3. The composite material of claim 1, wherein the magnetic material is present in the range of 5 to 40 parts by weight and the carbon-based conductive material is present in the range of 0.1 to 20.0 parts by weight of the thermoplastic resin.

4. The composite material of claim 1, wherein the thermal conductive layer comprises 0.1 to 20.0 parts by weight of the graphene nanoplate based on 100 parts by weight of the thermoplastic resin.

5. The composite material of claim 2, wherein the thermal conductive layer comprises 0.1 to 20.0 parts by weight of the graphene nanoplate based on 100 parts by weight of the thermoplastic resin.

6. The composite material of claim 1, wherein the electromagnetic wave-shielding layer comprises a film having a thickness of 10 to 300 μm.

7. The composite material of claim 3, wherein the electromagnetic wave-shielding layer comprises a film having a thickness of 10 to 300 μm.

8. The composite material of claim 1, wherein the thermoplastic resin comprises crystalline thermoplastic resin.

9. The composite material of claim 3, wherein the thermoplastic resin comprises crystalline thermoplastic resin.

10. The composite material of claim 1, wherein the thermoplastic resin comprises a mixture of one or more materials selected from the group consisting of polyethylene, polypropylene, polystyrene, polyalkylene terephthalate, polyamide resin, polyacetal resin, polycarbonate, polysulfone, and polyimide.

11. The composite material of claim 3, wherein the thermoplastic resin comprises a mixture of one or more materials selected from the group consisting of polyethylene, polypropylene, polystyrene, polyalkylene terephthalate, polyamide resin, polyacetal resin, polycarbonate, polysulfone, and polyimide.

12. The composite material of claim 1, wherein the magnetic material comprises a mixture of one or more materials selected from the group consisting of a metal-based material and a metal-based compound having high permeability.

13. The composite material of claim 3, wherein the magnetic material comprises a mixture of one or more materials selected from the group consisting of a metal-based material and a metal-based compound having high permeability.

14. The composite material of claim 2, wherein the graphene nanoplate has a thickness of 10 to 100 nm.

15. The composite material of claim 4, wherein the graphene nanoplate has a thickness of 10 to 100 nm.

16. The composite material of claim 2, wherein the thermoplastic resin comprises a mixture of one or more materials selected from the group consisting of polyethylene, polypropylene, polystyrene, polyalkylene terephthalate, polyamide resin, polyacetal resin, polycarbonate, polysulfone, and polyimide.

17. The composite material of claim 4, wherein the thermoplastic resin comprises a mixture of one or more materials selected from the group consisting of polyethylene, polypropylene, polystyrene, polyalkylene terephthalate, polyamide resin, polyacetal resin, polycarbonate, polysulfone, and polyimide.

18. The composite material of claim 2, wherein the thermoplastic resin of the thermally conductive layer comprises the same resin as the thermoplastic resin of the electromagnetic wave-shielding layer.

19. The composite material of claim 1, wherein the thermal conductive layer has a thickness of 0.5 to 5 mm.

20. The composite material of claim 1, wherein the electromagnetic wave-shielding layer comprises shaded stripe or lattice patterns on the surface of the electromagnetic wave-shielding layer.
